(19) United States
(12) Patent Application Publication
(10) Pub. No.: US 2015/0085462 A1
(43) Pub. Date: Mar. 26, 2015

(54) ELECTROMAGNETIC INTERFERENCE SHIELDING MATERIAL, ELECTROMAGNETIC INTERFERENCE SHIELDING DEVICE, METHOD FOR MAKING THE ELECTROMAGNETIC INTERFERENCE SHIELDING DEVICE, ELECTROMAGNETIC INTERFERENCE SHIELDING PACKAGE MODULE AND APPLIANCE

(71) Applicant: Yoshinari MATSUDA, Taipei City (TW)

(72) Inventor: Shiho OKAMOTO, Yokohama City (JP)

(73) Assignee: Yoshinari Matsuda, Taipei City (TW)

(21) Appl. No.: 14/037,812

(22) Filed: Sep. 26, 2013

(51) Int. Cl. H05K 9/00

(52) U.S. Cl. CPC H05K 9/0083
USPC 361/814; 252/478; 427/123; 428/220

(57) ABSTRACT

The present invention relates to an EMI shielding material that has a mixture that constitutes 70 wt % to 98 wt % of the EMI shielding material, wherein the mixture has: 1) a dendritic copper filler having copper dendritic crystals of lengths ranging from 0.1 μm to 50 μm, 2) a flaky copper filler having copper flakes of diameters ranging from 0.1 μm to 50 μm, 3) a resin binder, and 4) a diluent. The present invention also relates to an EMI shielding device made by applying the EMI shielding material on a surface of an electronic unit and by a following heating. The EMI shielding device has a volume resistivity of 10⁻⁵ to 10⁻³ acm. The invention also provides a method for making the EMI shielding device, a package module employing the foregoing EMI shielding device for shielding electromagnetic interference and an appliance employing the foregoing EMI shielding device.

### BACKGROUND OF THE INVENTION

1. Field of the Invention

The present invention relates to an electromagnetic interference (EMI) shielding material, especially to an EMI shielding material suitable for an EMI shielding package module. The present invention also relates to an EMI shielding device employing the foregoing EMI shielding material, a method for making said EMI shielding device, an EMI shielding package module employing the foregoing EMI shielding device, and an appliance employing the foregoing EMI shielding device for shielding electromagnetic interference.

2. Description of the Prior Art

There is an evitable trend of down-sizing appliances such as mobile phones, smart phones or personal internet devices (PID) into compact sizes and shapes, which in turn demands the use of compact chips and package modules for packaging said chips in making the compact appliances. Components of the appliance, for example, a wireless high-frequency unit for high-speed digitalization and wireless devices specifically requires effective EMI shielding. For packaging an antenna unit or other signal-receiving unit that is especially susceptible to EMI, a metal casing is employed for making a conventional EMI shielding device for shielding the unit from EMI to ensure expected operation as designed.

However, the metal casing for making the EMI shielding device has a considerable thickness which results into an increase of thickness of a conventional package module employing the conventional EMI shielding device, thus forbidding further down-sizing of appliances. In addition, the conventional EMI shielding device has a rigidly predefined shape that makes it difficult to adjust or modify the conventional EMI shielding device according to the adjusted or modified shape of the package module, An unmatched assembly of the conventional EMI shielding device into a package module may leave rimming portions unshielded, constituting severe EMI problems to be improved.

In order to address the aforementioned problem, another conventional EMI shielding means employs an EMI shielding silver membrane implemented by spreading a silver material on a surface. However, the conventional EMI shielding silver membrane imposes too high a cost burden. Furthermore, the silver membrane often fails to satisfyingly adhere to the surface, which is known to be a problem difficult to overcome.

Other conventional means include the utilization of copper evaporation and sputtering. It is noted, however, that although the material of the instant conventional means itself costs less than the aforementioned silver membrane, the equipments indispensible for implementing copper evaporation or sputtering are extremely expensive. Maintenance thereof is also a considerable burden. Besides, the instant conventional means of utilizing copper evaporation or sputtering does not cure the deficiency that the adhesiveness to the surface fails to reach an ideal level.

In addition to the foregoing conventional means, still another EMI shielding means includes copper plating: However, the implementation cost for copper plating is also unacceptably high and the aforementioned adhesiveness problem is yet to be overcome.

An EMI shielding means formed on a surface without proper adhesiveness, after being processed with retlow soldering, may result into severe flaws such as exfoliation and inflating deformation. It is thus known that the adhesion failure of conventional EMI shielding means and conventional EMI shielding materials is to be improved. The excessively high cost for the conventional means lowers competitiveness is also a problem to be solved. To overcome the shortcomings, the present invention provides an EMI shielding material to mitigate or obviate the aforementioned problems. The present invention, in order to address the aforementioned problems, also aims to provide an EMI shielding device employing the foregoing EMI Shielding material, a method for making said EMI shielding device, a package module employing the foregoing EMI shielding device for shielding electromagnetic interference, and an appliance employing the foregoing EMI shielding device for shielding EMI.

### SUMMARY OF THE INVENTION

The main objective of the invention is to provide an EMI shielding material that is adjustable to form in various shapes and thus may be conveniently used for shielding a package module from EMI, which contributes to down-sizing of compact appliance. Other aspects of the present invention provide subject matters including, but not limited to, an EMI shielding device employing the foregoing EMI shielding material, a method for making said EMI shielding device, a package module employing the foregoing EMI shielding device for shielding electromagnetic interference, and an appliance employing the foregoing EMI shielding device for shielding electromagnetic interference.

The EMI shielding material in accordance with the present invention has a mixture that constitutes 70 wt % to 98 wt % of the EMI shielding material, wherein the mixture has: 1) a dendritic copper filler having copper dendritic crystals of lengths ranging from 0.1 μm to 50 μm, 2) a flaky copper filler having copper flakes of diameters ranging from 0.1 μm to 50 μm, 3) a resin binder, and 4) a diluent. The resin binder comprises at least epoxy resin, phenol resin, polyester, melamine resin, a defoamer and an antisettling agent. The diluent is used to lower viscosity and comprises at least diethylene glycol monobutyl ether.

An EMI shielding device in accordance with the present invention, which provides EMI shielding effects, is made by applying the foregoing EMI shielding material on a surface of an electronic unit to be shielded and by a following heating of the material at a temperature ranging from 120 degrees Celsius to 160 degrees Celsius for 30 minutes to one hour so as to harden the same to form the EMI shielding device that has a volume resistivity of 10⁻⁵ to 10⁻³ acm. The aforementioned EMI shielding material may be applied on the surface of the package by means of screen printing or spraying to form the EMI shielding device and a package module. Thus the EMI shielding material may be adjusted or modified according to the design of the package module, which also contributes to effectively limit the thickness of the package module and make compact packaging possible, while maintaining effective EMI shielding. It is then evident that employing the foregoing EMI shielding device would contribute to down-sizing of an appliance. In addition, the EMI shielding material is inexpensive yet convenient to be implemented without excessive cost. As a result, the present invention is indeed capable of improving the deficiency of conventional means and providing a low-cost EMI shielding device that appropriately adheres to the surface of the package module. Based on the foregoing fact of the effectiveness of the EMI shielding material, device and method for making the device in accordance to the present invention, it is also apparent that the present invention is capable of providing a package module shielded from EMI and relevant appliances.

Other objectives, advantages and novel features of the invention will become more apparent from the following detailed description when taken in conjunction with the accompanying drawings.

### BRIEF DESCRIPTION OF THE DRAWINGS

FIG. 1 is a side view in partial section of a package module in accordance with the present invention;

FIG. 2 is a side view in partial section of another package module in accordance with the present invention;

FIG. 3 is a schematic diagram of an antenna module in accordance with the present invention;

FIG. 4 is a top view of an electronic unit employing a package module in accordance with the present invention;

FIG. 5 is a side view of the electronic unit of FIG. 4;

FIG. 6 is a schematic diagram of a conventional antenna module in accordance with the prior art;

FIG. 7 is a top view of a conventional electronic module in accordance with the prior art; and

FIG. 8 is a side view of the conventional electronic module in FIG. 7.

### DETAILED DESCRIPTION OF THE PREFERRED EMBODIMENTS

### Embodiment 1

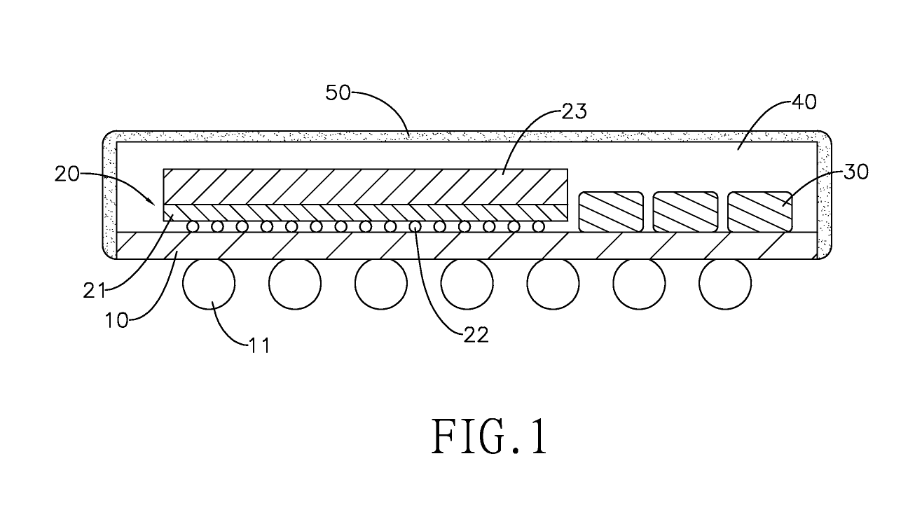

With reference to FIG. 1, an embodiment in accordance with the present invention to be hereinafter described relates to an EMI shielding device, which was made from the EMI shielding material in accordance with the present invention, implemented to an EMI shielding package module of an appliance.

The EMI shielding package module comprises a package body and a thin film shaped EMI shielding device 50.

The package body comprises a packaging material 40 and at least one electronic unit. The at least one electronic unit is to be packaged within the packaging material 40 with the connectivity to the outer environment of the electronic unit being maintained. The electronic unit is a unit susceptible to EMI that requires proper shielding, such as a radio frequency identification (RFID) unit, a wireless communication unit, or a signal-receiving unit. In the instant embodiment, a chip 20 and multiple inner units 30 constitute an electronic unit to be packaged in the packaging material 40. The chip 20 and the multiple inner units 30 are operably attached to a substrate 10. The substrate 10 comprises multiple solder balls 11, which are employed in solutions such as a ball grid array (BGA). The chip 20 and the multiple inner units 30 can therefore maintain the connectivity to the outer environment through the substrate 10 and the aforementioned solder balls 11.

Specifically, the chip 20 may be suitable for an implementation of BGA or of other similar solutions. In the instant embodiment, the chip 20 comprises a chip-substrate 21, a chip body 23 and multiple chip-solder balls 22. The chip-substrate 21 comprises two opposite surfaces. The chip body 23 is operably attached to one of the surfaces of the chip-substrate 21. The chip-solder balls 22 are attached to the other surface of the chip-substrate 21. The multiple chip-solder balls 22 are connected to the substrate 10 and therefore are capable of electrical connection to the outer environment through the substrate 10 and the solder balls 11.

The EMI shielding device 50 is spread on a surface of the aforementioned package body. In the instant embodiment, the package body comprises the aforementioned packaging material 40 and at least one electronic unit, wherein each electronic unit comprises the chip 20 and the multiple inner units 30. Therefore the EMI shielding device 50 is spread on a surface of the packaging material 40 and covers rimming portions of the package body, which includes a junction of the packaging material 40 and the substrate 10 and the rimming portions of the substrate 10 itself. Said surface of the packaging material 40 is hereinafter referred to as “packaging surface.”

The EMI shielding device 50 is a membrane formed with an EMI shielding material. The EMI shielding material comprises a mixture. The mixture constitutes 70 wt % to 98 wt % of the EMI shielding material. The mixture comprises a dendritic copper filler, a flaky copper filler, a resin binder and a diluent. The dendritic copper filler comprises copper dendritic crystals of lengths ranging from 0.1 μm to 50 μm. The flaky copper filler comprises copper flakes of diameters ranging from 0.1 μm to 50 μm. The resin binder comprises at least epoxy resin, phenol resin, polyester, melamine resin, defoamer and an antisettling agent. The diluent is used to lower viscosity and comprises at least diethylene glycol monobutyl ether. As disclosed in the instant embodiment, the EMI shielding material in accordance with the present invention is implemented without silver, which allows the EMI shielding material free from problems or flaws due to silver migration. Further, the EMI shielding material in accordance with the present invention without silver may be referred to as a copper ink or a copper paste.

The EMI shielding material, comprising the aforementioned mixture, is heated for hardening the same at a temperature ranging from 120 degrees Celsius to 160 degrees Celsius for 30 minutes to one hour to achieve a volume resistivity of 10⁻⁵ to 10⁻³ Ω·cm.

In order to appropriately provide shielding from EMI according to the shape of the package module, the EMI shielding device 50 is formed by spreading the EMI shielding material into a membrane and baked for hardening the membrane at a temperature ranging from 120 degrees Celsius to 160 degrees Celsius for 30 minutes to one hour.

In the instant embodiment, the EMI shielding device 50 is a membrane having a thickness of 1 μm to 50 μm, which is made from the EMI shielding material as described above. Specifically, the EMI shielding material is screen-printed or sprayed on the package body to form a membrane, wherein the membrane is heated and hardened to form the EMI shielding device 50. When making the EMI shielding device 50, the EMI shielding material is conveniently and effectively spread according to the shape of the package body, and thus is capable of covering the portions, including the rimming portions of the package body, to be shielded from EMI.

When screen printing is used to print the EMI shielding material, the package body is loaded on a tray for a screen printing process, so as to conveniently print the EMI shielding material not only on a top surface of the package body but also on the side surfaces and rimming portions. After the screen printing process, the package body and the tray on which the package body is loaded are baked in an oven for heating to harden the EMI shielding material.

When spraying is used to spread the EMI shielding material, it is also recommended to use the aforementioned heat-resistant tray for effective and thorough spraying of the EMI shielding material on the top surface, side surfaces and rimming portions of the package body. A pre-drying process is performed before baking. The baking process is as described above to bake the package body on the tray in the oven. In order to facilitate the spraying process, it is preferred to make the binder for the aforementioned EMI shielding material from phenol resin and epoxy resin with polyester. Said binder is mixed with the dendritic copper filler comprising copper dendritic crystals of lengths ranging from 0.1 μm to 50 μm, the flaky copper filler comprising copper flakes of diameters ranging from 0.1 μm to 50 μm, and a diluent being diethylene glycol monobutyl ether for lowering viscosity to an extent suitable for spraying. In addition, if the electronic unit comprises a member to which grounding (GND) is necessary, a site is left exposed for grounding when packaging the packaging material 40. In the process of spreading the EMI shielding material, the exposed site is grounded by the spread EMI shielding material or electrically connected to the solder balls 11. For example, it is preferred that the spray-spreading of the EMI shielding be performed on the top surface and the side surfaces of the package body such that the EMI shielding material is electrically connected to a GND site thereof and at the same time effectively provides shielding from EMI. In terms of feasibility, a spray-spread EMI Shielding material of a thickness ranging from 1 μm to 50 μm is sufficient to provide the functionality of EMI shielding.

As disclosed above, by means of screen printing or spraying, the present invention spread the foregoing EMI shielding material to form an EMI shielding device for shielding a package module. The present invention not only effectively shields the package module from EMI according to the shape of the package module, but also has a thickness not limited by a predetermined design, which is the case of a conventional EMI shielding device employing a metal casing with predefined thickness being an obstacle to down-sizing of modern appliances. In contrast, the present invention employs an easy-to-practice method to adopt a low-cost material for adhesion, which greatly helps to save space and contribute to thickness-decreasing. Specifically, the structure as demonstrated in the instant embodiment helps to significantly decrease a thickness of a module, which would have else had a thickness of 1.38 μm to 1.25 μm.

### Embodiment 2

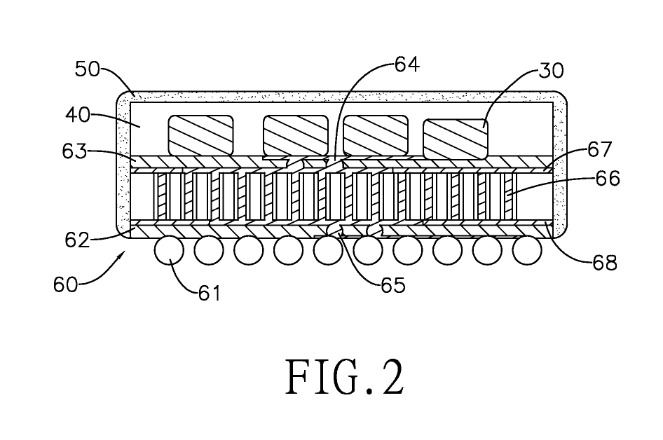

With reference to FIG. 2, the instant embodiment demonstrates another mode of practice in accordance with the present invention, The instant embodiment is largely the same as the foregoing embodiment 1, except that the instant embodiment employs a through-silicon via (TSV) chip 60, instead of a chip 20 as described in Embodiment 1. The chip 20 used in Embodiment 1, which comprises the chip-substrate 21 and chip-solder balls 22, demands a considerable space. In contrast, the TSV chip 60, which is capable of building multi-dimensional connections via guide holes 66, helps to save space taken by the chip-substrate 21 and the chip-solder balls 22. The structure of the TSV chip 60 thus forms a three-dimensional structure which is densely structured and significantly contributes to down-sizing of appliances. The instant embodiment comprises the aforementioned TSV chip 60. The TSV chip 60 comprises multiple guide holes 66. The guide holes 66 communicate between a chip bottom 62 and a chip top 63 through a top laminate structure 67 and a bottom laminate structure 68. A connection material is mounted in the guide holes 66 and comprises a top portion 64 and a bottom portion 65. The top portion 64 is electrically connected to the aforementioned inner units 30 through the chip top 63 and the top laminate structure 67. The bottom portion 65 is electrically connected to solder balls 61 through the chip bottom 62 and the bottom laminate structure 68 for building electric connection to the outer environment.

The TSV chip 60 and the packaging material 40 constitute a package body. The instant embodiment also applies the aforementioned EMI shielding material to form an EMI shielding device 50 by a spreading means such as screen printing or spraying on the package body. The EMI shielding material is spread on a top surface and side surfaces of the package body extending to a rimming portion of the TSV chip 60, the bottom laminate structure 68 and the chip bottom 62 thereof.

### Embodiment 3

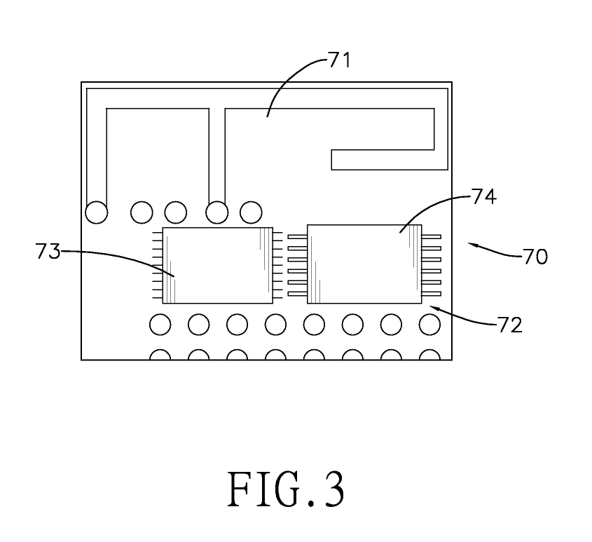

With reference to FIG. 3, the instant embodiment demonstrates the application of the present invention to an antenna module 70, suitable examples of which include a ZigBee wireless communication module. The antenna module 70 comprises an antenna circuit 71 and a controlling circuit 72. The controlling circuit 72 comprises at least one electronic unit. In the instant embodiment, the controlling circuit 72 comprises a first electronic unit 73 and a second electronic unit 74. The first electronic unit 73 and the second electronic unit 74 are packaged with the aforementioned EMI shielding material and the foregoing TSV chip is employed, so as to contribute to down-sizing.

Specifically, the antenna module 70 is packaged by means of large scale integration (LSE) or surface-mount technology (SMT) to form a package body with a protective insulating resin. The package body is then spread with the aforementioned EMI shielding material for shielding from EMI and thus completes a packaging process. As disclosed above, when spreading the EMI shielding material, spreading means such as spraying may be employed. The composition of the EMI shielding material is also the same as described in the foregoing embodiments and comprises a mixture which constitutes 70 wt % to 98 wt % of the EMI shielding material. The mixture comprises a dendritic copper filler having copper dendritic crystals of lengths ranging from 0.1 μm to 50 μm, a flaky copper filler having copper flakes of diameters ranging from 0.1 μm to 50 μm, a resin binder and a diluent.

A printing process, so called. copper paste printing, may be performed to print the EMI shielding material onto the surfaces of the package body formed with the protective insulating resin in order to form an antenna wire, or to form an antenna element on a surface of the insulating resin of the package body, wherein the antenna element is commonly found in, for example, an RFID unit. It is thus apparent that the present invention suitable for making a unit comprising an antenna wire or an antenna element, and at the same time capable of contributing to down-sizing of appliances.

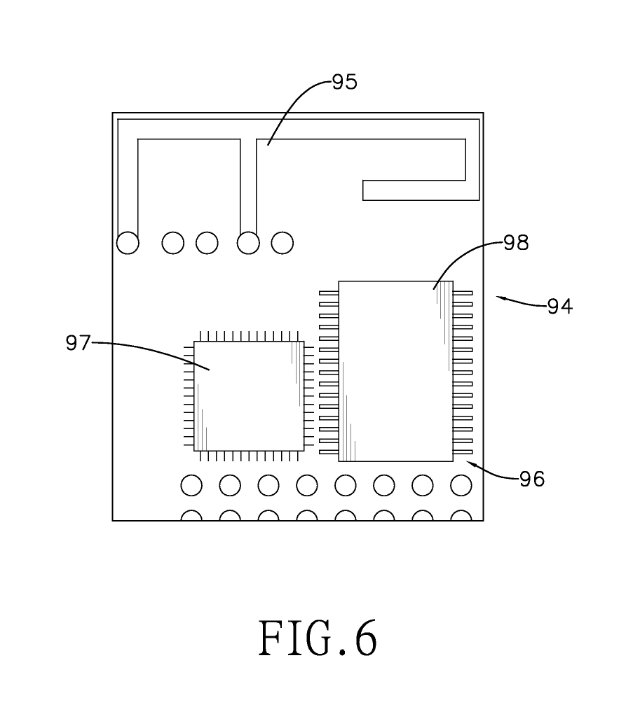

A conventional antenna module 94, as shown in FIG. 6, comprises an antenna circuit 95 and a controlling circuit 96, wherein the controlling circuit 96 comprises a first electronic unit 97 and a second electronic unit 98.

The instant embodiment improves the structure of the conventional antenna module by applying the present invention to allow down-sizing of appliances. In terms of manufacture and down-sizing of electronic appliances, the antenna module 70 saves more space than the conventional antenna module 94 and thus contributes to manufacturing compact or thin appliances.

### Embodiment 4

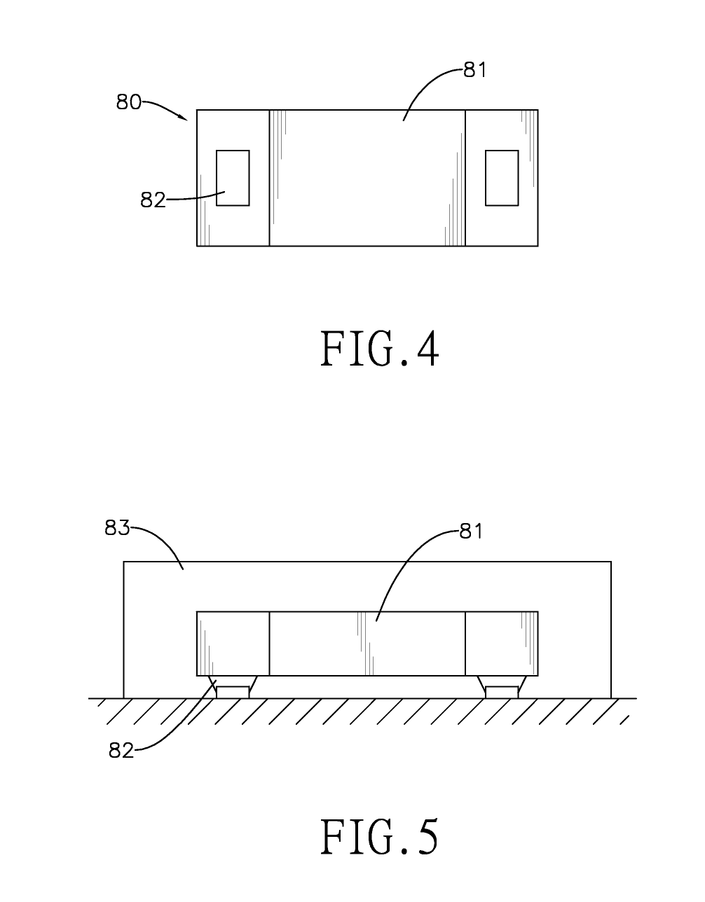

With reference to FIGS. 4 and 5, the instant embodiment relates to an electronic unit 80 packaged with a packaging material 83, The electronic unit 80 comprises a unit body 81 and two pads 82. The unit body 81 comprises two electrodes which are respectively formed on two ends of the unit body 81. The two pads 82 are respectively mounted to the two electrodes of the unit body 81. Each pad 82 has a surface having an area smaller than an area of a surface of the electrode to which the pad 82 is mounted. Each pad 82 is tapered such that its diameter decreases along the direction away from the electrode to which it is mounted.

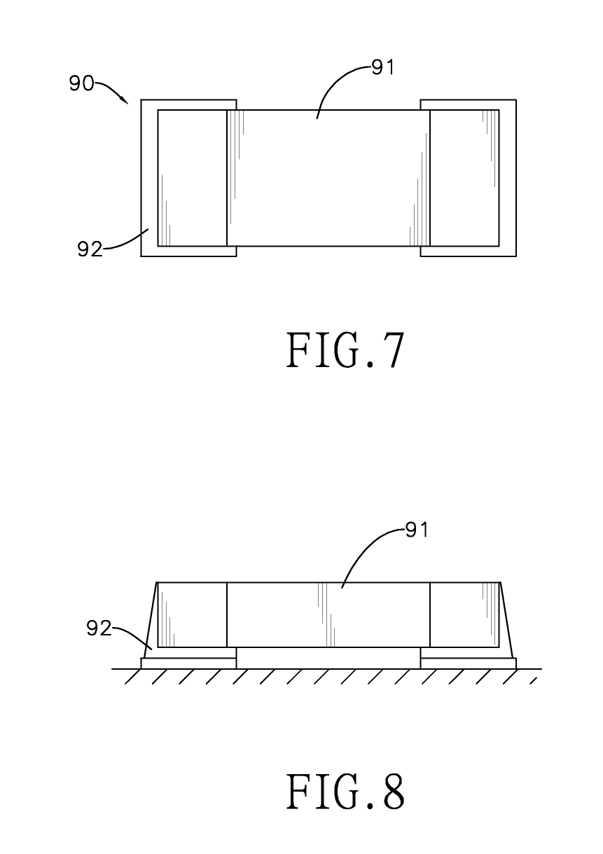

On the contrary, a conventional electronic module 90, as shown in FIGS. 7 and 8, comprises a body 91 and two pads 92. The pads 92 are respectively mounted to two electrodes respectively formed on two ends of the body 91. Each of the pads 92 has an outward-expanding shape such that the diameter increases outwards.

The instant embodiment provides a structure that effectively overcomes a deficiency Of the conventional module 90 that the pads 92 are excessively large. These excessively large pads 92 not only raise the difficulty of packaging, but also lead to wasting of solder materials. The instant embodiment utilizes the packaging material 83 to protect the pads 82 so as to elongate the lives and structural strengths thereof. Further, smaller solder points are made possible with the structures of the pads 82 of the instant embodiment. In addition, when employing the TSV chip 60 as shown in FIG. 2, the advantages of the guide holes 66 and the connection material mounted in the guide holes 66 as aforementioned may also be applied to the instant embodiment to form outward structures, such as solder points, for building electrical connections.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. An EMI shielding material comprising:
a mixture constituting 70 wt % to 98 wt % of the EMI shielding material and comprising:
a dendritic copper filler comprising copper dendritic crystals of lengths ranging from 0.1 μm to 50 μm;
a flaky copper filler comprising copper flakes of diameters ranging from 0.1 μm to 50 μm;
a resin. binder comprising at least epoxy resin, phenol resin, polyester, melamine resin, a defoamer and an antisettling agent; and
a diluent for lowering viscosity comprising at least diethylene glycol monobutyl ether.

2. The EMI shielding material claimed in claim 1, wherein the EMI shielding material is heated and hardened at a temperature ranging from 120 degrees Celsius to 160 degrees Celsius for 30 minutes to one hour and has a volume resistivity of 10⁻⁵ to 10⁻³ Ω·cm.

3. An EMI shielding device being a membrane made from the EMI shielding material as claimed in claim 2 and having a thickness of to 50 μm.

4. The EMI shielding device as claimed in claim 3, wherein he membrane is obtained by spreading the EMI shielding material by a means selected from a group consisting of screen printing and spraying, and by a following heating and hardening at a temperature ranging from 120 degrees Celsius to 160 degrees Celsius for 30 minutes to one hour

5. A method for making an EMI shielding device, the method comprising:
obtaining the EMI shielding material as claimed in claim 2;
spreading the EMI shielding material;
heating and hardening the spread EMI shielding material at a temperature ranging from 120 degrees Celsius to 160 degrees Celsius for 30 minutes to one hour; and
obtaining a membrane being the EMI shielding device:

6. The EMI shielding material as claimed in claim 1, wherein the EMI shielding material is spread by a means selected from a group consisting of screen printing and spraying.

7. An EMI shielding package module comprising:
a package body comprising a packaging material and at least one electronic unit, wherein the at least one electronic unit is packaged within the packaging material and is capable of connection o an outer environment; and
an EMI shielding device as claimed in claim 3 being spread on a surface of the package body.

8. The EMI shielding package module as claimed in claim 7, wherein the at least one electronic unit comprises at least one electronic unit selected from a group consisting of a wireless high-frequency unit, a wireless communication unit and a signal-receiving unit.

9. The EMI shielding package module as claimed in claim 7, wherein the at least one electronic unit comprises at least one TSV chip.

10. The EMI shielding package module as claimed in claim 7, wherein
the at least one electronic unit comprises multiple electrodes;
each of the electrodes has a pad mounted to a surface of the electrode; and
each pad has a surface having an area smaller than an area of the Surface of the electrode to which the pad is mounted.

11. The EMI shielding package module as claimed in claim 10, wherein each pad is tapered. such that a diameter thereof decreases along the direction away from the electrode to which the pad is mounted.

12. An appliance comprising the EMI shielding package module as claimed in claim 7.
